(19) United States
(12) Patent Application Publication
(10) Pub. No.: US 2026/0344218 A1
(43) Pub. Date: Oct. 29, 2026

(54) DISPLAY DEVICE

(71) Applicant: LG Display Co., Ltd., Seoul (KR)

(72) Inventors: Sunggon HONG, Paju-si (KR); Minsu KIM, Paju-si (KR); Youngtaek HONG, Paju-si (KR); Jongchan PARK, Seoul (KR)

(73) Assignee: LG Display Co., Ltd., Seoul (KR)

(21) Appl. No.: 19/630,388

(22) Filed: Mar. 26, 2026

(30) Foreign Application Priority Data
Apr. 29, 2025 (KR) 10-2025-0056045

(51) Int. Cl. H10K 59/131; H10K 59/122; H10K 59/80; H10K 102/00

(52) U.S. Cl. CPC H10K 59/131; H10K 59/122; H10K 59/873; H10K 2102/311

(57) ABSTRACT

A display device according to one embodiment includes a substrate including a display area and a non-display area around the display area, a voltage line disposed in the non-display area on the substrate, and a bank around the power line, wherein the voltage line includes a first portion extending in a first direction and a second portion positioned in a second direction intersecting the first direction from the first portion and having a curved shape, the second portion is provided as a plurality of second portions, which are disposed to be spaced apart from each other in the first direction, and the second portion disposed close to the display area among the plurality of second portions is covered by the bank.

### CROSS REFERENCE TO RELATED APPLICATION

The present application claims priority to Korean Patent Application No. 10-2025-0056045, filed Apr. 29, 2025, the entire contents of which is incorporated herein for all purposes by this reference.

### BACKGROUND

### Technical Field

The present specification relates to a display device.

### Description of the Related Art

As the information society develops, various demands for display devices for displaying images are increasing, and various types of display devices, such as liquid crystal display (LCD) devices, organic light-emitting diode (OLED) display devices, etc., are utilized.

A display device includes a plurality of pixels and a plurality of switching elements for driving and controlling the pixels.

### BRIEF SUMMARY

The present disclosure relates to a structural configuration of power lines in a non display area of a flexible display panel to improve moisture resistance and mechanical reliability. The low potential and high potential voltage lines include curved portions (e.g., second portions) that protrude from a linear portion (e.g., first portion) and are spaced apart along the line. This geometry increases the moisture permeation path and delays moisture ingress. In addition, through holes formed in upper metal layers of the power lines allow gas generated in underlying organic layers to escape, thereby reducing the likelihood of blistering and delamination.

The second portions of the power lines, particularly those located closest to the display area, are selectively covered by a bank structure to reduce stress concentration and suppress crack initiation and propagation in encapsulation layers. A first cover pattern is provided to directly contact and cover multilayer metal protrusions of the curved portions, such as titanium aluminum titanium stacks. By covering protruding metal tips that would otherwise create localized stress concentration, the first cover pattern reduces cracking in the encapsulation layer.

In another embodiment, a second cover pattern is arranged above selected first cover patterns to provide additional stress redistribution in the vertical direction. The coordinated arrangement of a dam, a first stopper, and a second stopper, aligned with the spacing of the curved portions, further limits crack propagation toward the display area. These structural features provide a layered mechanical and moisture management approach for bendable display panels, particularly in the non display area, to enhance durability and long term reliability.

Various embodiments of the present specification are directed to providing a display device capable of increasing a moisture permeation path.

Various embodiments of the present specification are also directed to providing a display device capable of preventing cracks in an embossed pattern (or a second portion, or a hammer pattern portion).

Various embodiments of the present specification are also directed to providing a display device capable of reducing the stress applied to an embossed pattern (or a second portion).

Various embodiments of the present specification are also directed to providing a display device capable of preventing cracks in a first encapsulation layer.

Various embodiments of the present specification are also directed to providing a low-power display device capable of extending lifetime.

Technical benefits of the present specification are not limited to the above benefits, and other benefits may be inferred from the following embodiments.

According to one embodiment, there is provided a display device including a substrate including a display area and a non-display area around the display area, a voltage line disposed in the non-display area on the substrate, and a bank around the power line, wherein the voltage line includes a first portion extending in a first direction and a second portion positioned in a second direction intersecting the first direction from the first portion and having a curved shape, the second portion is provided as a plurality of second portions, which are disposed to be spaced apart from each other in the first direction, and a second portion disposed close to the display area among the plurality of second portions is covered by the bank.

According to one embodiment, there is provided a display device including a substrate including a display area and a non-display area around the display area, a voltage line disposed in the non-display area on the substrate, a first cover pattern, a dam overlapping the power line, a first stopper between the dam and the display area, and a second stopper between the first stopper and the dam, wherein the voltage line includes a first portion extending in a first direction, and a second portion positioned in a second direction intersecting the first direction from the first portion and having a curved shape, the second portion is provided as a plurality of second portions, which are disposed to be spaced apart from each other in the first direction, the dam and the first stopper continuously extend in the second direction, the second stopper overlaps the first portion and is disposed between adjacent second portions in the second direction, and the first cover pattern overlaps the plurality of second portions disposed to be spaced apart from each other in the first direction.

Detailed matters of other embodiments are included in the detailed description and accompanying drawings.

### BRIEF DESCRIPTION OF THE SEVERAL VIEWS OF THE DRAWINGS

FIG. 1 is a plan view of a display device according to one embodiment.

FIG. 2 is a cross-sectional view illustrating a bent state of the display panel according to FIG. 1.

FIG. 3 is a plan view illustrating a bent state of the display device according to FIG. 1.

FIG. 4 is a cross-sectional view along line B-Bʹ in FIG. 3.

FIG. 5 is a cross-sectional view along line C-Cʹ in FIG. 3.

FIG. 6 is a cross-sectional view along line A-Aʹ in FIG. 1.

FIG. 7 is an enlarged plan view of area Q1 in FIG. 1.

FIG. 8 is a cross-sectional view along line D-Dʹ in FIG. 7.

FIG. 9 is a cross-sectional view along line E-Eʹ in FIG. 7.

FIG. 10 is a cross-sectional view of the display panel according to still another embodiment.

FIG. 11 is a cross-sectional view along line F-Fʹ in FIG. 10.

FIG. 12 is an enlarged cross-sectional view of area Q2 in FIG. 11.

FIG. 13 is a plan view of a display panel according to another embodiment.

FIG. 14 is a cross-sectional view along line G-Gʹ in FIG. 13.

### DETAILED DESCRIPTION

Hereinafter, various embodiments will be described with reference to the accompanying drawings.

The same reference numerals indicate the same components.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In the specification, when a certain component (or an area, a layer, a portion, etc.) is described as “on,” “connected,” or “coupled to” another component, it means that the certain component may be directly connected/coupled to another component or still another component may be disposed therebetween.

To further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

The term “and/or” includes all one or more combinations that may be defined by the associated configurations.

Terms such as “first,” “second,” and the like may be used to describe various components, but the components are not limited by the terms. The terms are used only for the purpose of distinguishing one component from another. For example, a first component may be referred to as a second component, and similarly, the second component may also be referred to as the first component without departing from the scopes of various embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc., can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

It should be understood that terms such as “includes” or “has” are intended to specify the presence of features, numbers, steps, operations, components, parts, or a combination thereof described in the specification and does not preclude the presence or addition possibility of one or more other features, numbers, steps, operations, components, parts, or combinations thereof in advance.

In the present disclosure, the term 'power line' refers to a conductive member or a conductive structure disposed in the non-display area (NDA) of the substrate. The voltage line is configured to supply driving voltages to the pixels (PX) of the display area (DA) and may include, for example, a high-potential voltage line (VDDL), a low-potential voltage line (VSSL), or a combination thereof. Structurally, the voltage line comprises a first portion extending in a first direction and at least one second portion (also referred to as an embossed pattern, hammer pattern portion, or curved portion) that intersects the first portion and possesses a rounded or oval shape. The voltage line may further include a third portion connecting the first and second portions. This voltage line may be formed of a single layer or multiple layers, such as a stacked metallic structure (e.g., Ti/Al/Ti), and may include holes (H) for discharging gas from underlying organic layers.

Features of various embodiments of the present specification may be coupled or combined partially or entirely, various technological interworking and driving are made possible, and various embodiments may be implemented independently of each other or implemented together in an associated relationship.

Hereinafter, a display device of the present specification will be described with reference to the accompanying drawings and embodiments as follows.

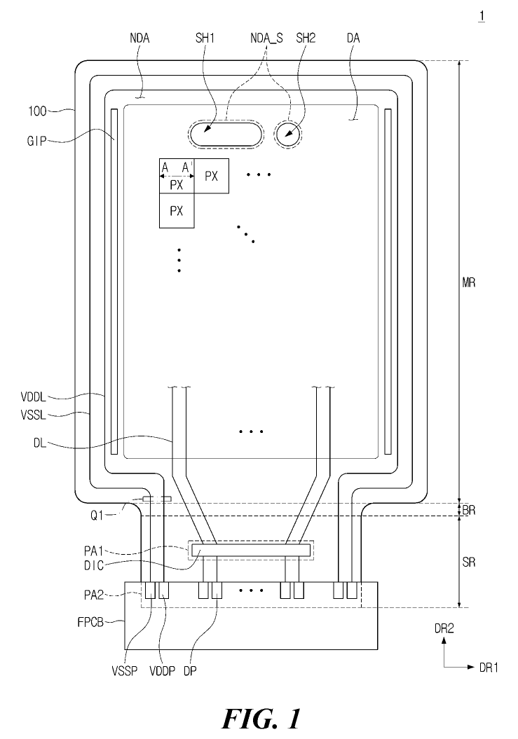

FIG. 1 is a plan view of a display device according to one embodiment.

Referring to FIG. 1, a display device 1 according to one embodiment may include a display panel 100. The display panel 100 may include a display area DA including a plurality of pixels PX and a non-display area NDA around the display area DA. The flat surface shape of the display area DA may have a rectangular shape. However, various embodiments of the present specification are not limited thereto, and the flat surface shape of the display area DA may be a square, circular, elliptical, or other polygonal shapes. For example, the display area DA may have a rectangular shape with rounded corners, but is not limited thereto, and may also have a rectangular shape with angled corners.

In various embodiments, a first direction DR1 and a second direction DR2 are different directions and intersect each other, for example, directions that intersect vertically in a plan view. In FIG. 1, the first direction DR1 may be generally the same as an extension direction of short edges of the display panel 100, and the second direction DR2 may be the same as an extension direction of long edges of the display panel 100. However, the directions described in various embodiments should be understood as indicating relative directions, and various embodiments are not limited to the described directions.

The display area DA may include short edges extending in the first direction DR1 and long edges extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and sensor holes SH1 and SH2 surrounded by the sensor non-display area NDA_S. The sensor holes SH1 and SH2 may be surrounded by the display area DA in a plan view. The sensor holes SH1 and SH2 may be, for example, two sensor holes as in FIG. 1, but various embodiments of the present specification are not limited thereto. For example, the sensor hole may be provided as one sensor hole. The two sensor holes SH1 and SH2 may each include a sensor hole in which an infrared sensor is disposed and a sensor hole in which a camera sensor is disposed, but various embodiments of the present specification are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S. In some embodiments, the sensor holes SH1 and SH2 are not disposed, and an infrared sensor or a camera sensor may be disposed in the display area DA. In this case, the number of pixels PX per area of the display area DA in which the infrared sensor or the camera sensor is disposed may be less than the number of pixels PX per area of the display area DA in which the infrared sensor or the camera sensor is not disposed. That is, the display area DA in which the infrared sensor or the camera sensor is disposed may further include a transmissive area.

A gate driving unit GIP may be disposed in the non-display area NDA positioned at the one side and the other side of the display area DA in the first direction DR1. A low-potential voltage line VSSL may be disposed outside the gate driving unit GIP on the non-display area NDA. For example, as illustrated in FIG. 1, the low-potential voltage line VSSL may extend from a printed circuit board FPCB, pass a sub-region SR and a bending region BR, may be positioned outside the gate driving unit GIP on the non-display area NDA, and disposed to surround the display area DA. A high-potential voltage line VDDL may be disposed outside the gate driving unit GIP on the non-display area NDA. The high-potential voltage line VDDL may be disposed between the low-potential voltage line VSSL and the gate driving unit GIP.

The non-display area NDA positioned at the other side of the display area DA in the second direction DR2 may extend further from a central portion of the other side toward the other side of the display area DA in the second direction DR2. A width of the non-display area NDA in the first direction DR1 further extending from the central portion of the other side toward the other side of the display area DA in the second direction DR2 may be smaller than a width of the non-display area NDA in the first direction DR1 adjacent to the other side of the display area DA in the second direction DR2.

The display device 1 may include a main region MR, the sub-region SR, and the bending region BR between the main region MR and the sub-region SR. The display area DA and the non-display area NDA surrounding four surfaces of the display area DA may form the main region MR, and a portion extending from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 positioned at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. A plurality of pads connected to the data driving unit DIC and the printed circuit board FPCB may be disposed in each of the first pad area PA1 and the second pad area PA2. The data driving unit DIC may be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but various embodiments of the present specification are not limited thereto, and the data driving unit DIC may be disposed by a chip on glass or chip on film method.

A plurality of pads may be disposed in the second pad area PA2. The plurality of pads may include the power pads (the low-potential voltage pad VSSP, the high-potential voltage pads VDDP), and data voltage pads DP. The data voltage pads DP may be disposed on a central portion of the second pad area PA2, and the low-potential voltage pad VSSP and the high-potential voltage pad VDDP may be disposed on an outer edge portion of the second pad area PA2. The high-potential voltage pad VDDP may be disposed between the low-potential voltage pad VSSP and the data voltage pad DP. The voltage pads VDDP and VSSP may be disposed on left and right sides of the second pad area PA2, respectively. The data voltage pad DP may be connected to a data line DL. The data line DL may be connected to each of the pixels PX in the display area DA.

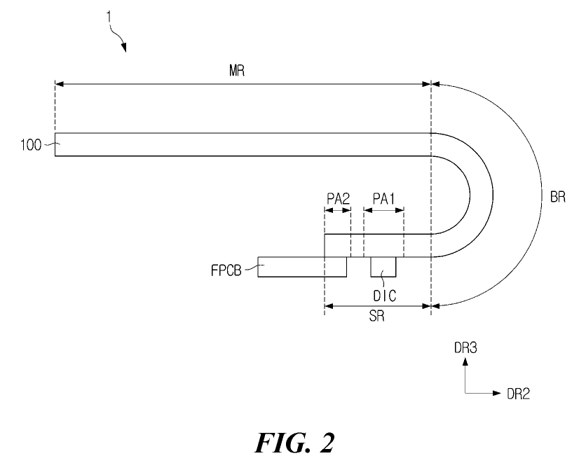

FIG. 2 is a cross-sectional view illustrating a bent state of the display panel according to FIG. 1.

Referring to FIG. 2, the bending region BR of the display panel 100 of the display device 1 according to one embodiment may be bent in a thickness direction (or a third direction DR3). Accordingly, the main region MR and the sub-region SR may overlap each other in the thickness direction. The display panel 100 may be bent such that a lower surface of the main region MR faces an upper surface of the sub-region SR. The printed circuit board FPCB may be attached to an end portion of the sub-region SR.

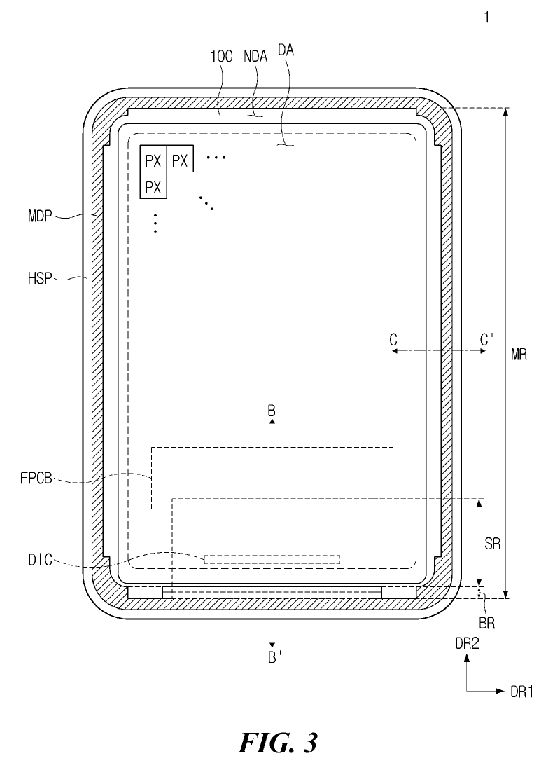

FIG. 3 is a plan view illustrating a bent state of the display device according to FIG. 1.

Referring to FIG. 3, the display device 1 may further include a mold part MDP. The mold part MDP may be positioned on an upper short edge of the display panel 100 in the second direction DR2, left and right long edges of the display panel 100, corners of the display panel 100, and a lower short edge of the display panel 100 in the second direction DR2.

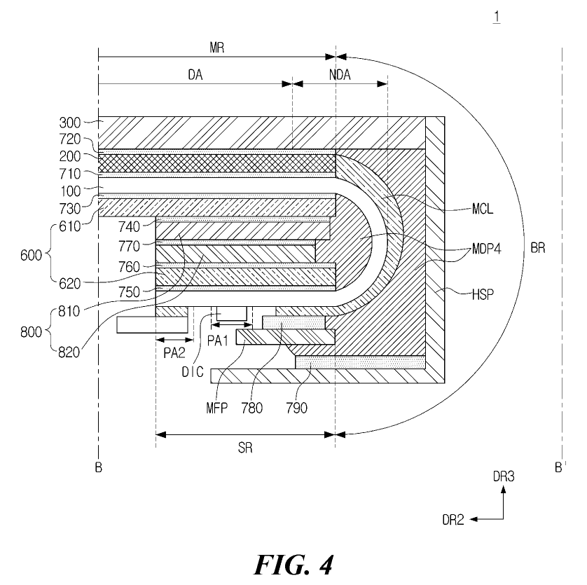

FIG. 4 is a cross-sectional view along line B-Bʹ in FIG. 3.

Referring to FIGS. 3 and 4, the display device 1 may include the display panel 100, a polarization layer 200, a cover layer 300, a backplate layer 600, a plate layer 800, bonding layers 710, 720, 730, 740, 750, 760, 770, 780, and 790, a cover layer MCL, the mold part MDP, a mold frame MFP, and a housing HSP.

The bending region BR of the display panel 100 may have a curved shape and may be bent in the thickness direction. The main region MR and the sub-region SR of the display panel 100 may overlap each other.

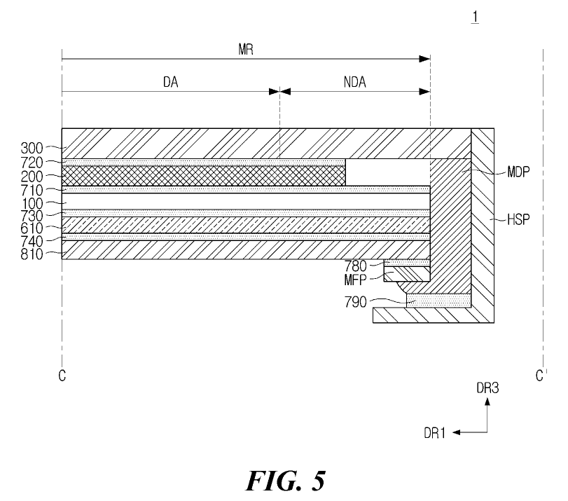

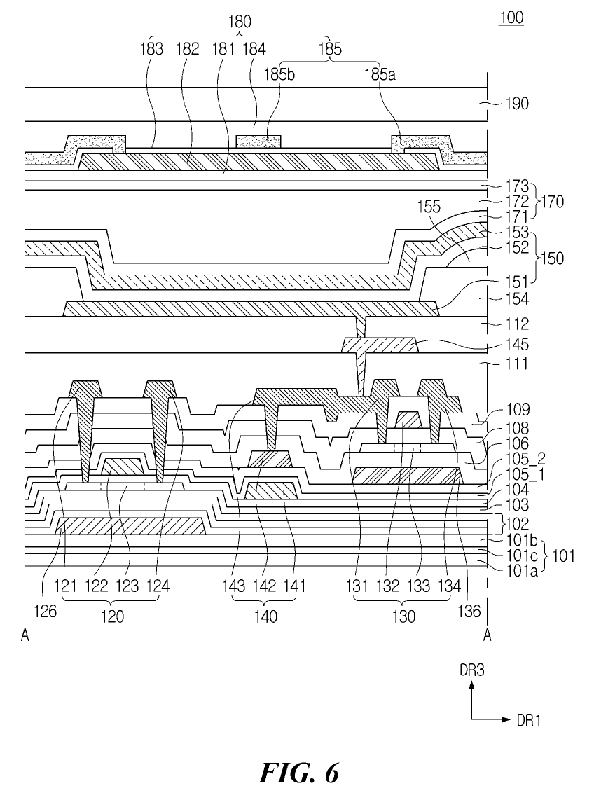

The polarization layer 200 may be disposed on the main region MR of the display panel 100. The polarization layer 200 may polarize light emitted from the display panel 100 at a polarization angle. The polarization layer 200 may emit light polarized at the polarization angle to the outside. The polarization layer 200 may include a function of blocking reflection of light not including the light polarized at the polarization angle among external light. The polarization layer 200 may include a first phase retardation layer, a second phase retardation layer on the first phase retardation layer, and a polarization layer on the second phase retardation layer. In FIGS. 5 and 6, the polarization layer 200 and the display panel 100 are illustrated as being separated, but are not limited thereto, and the polarization layer 200 may be included in the display panel 100. In some embodiments, the polarization layer 200 may be omitted and a color filter may be disposed.

The cover layer 300 may be disposed on the polarization layer 200. The cover layer 300 may be made of a glass material including glass, quartz, etc., but various embodiments of the present specification are not limited thereto, and the cover layer 300 may be made of a plastic material. The cover layer 300 may be disposed above the display panel 100 to protect members disposed below the cover layer 300 from the outside. The cover layer 300 may be formed by chemical reinforcement, but various embodiments of the present specification are not limited thereto. The cover layer 300 may be a cover window, a window cover, or a cover member, but various embodiments of the present specification are not limited thereto. Various embodiments of the present specification are not limited thereto.

The cover layer 300 can protect the members disposed below the cover layer 300 from the outside, but as described above, since the cover layer 300 is made of a glass material, the cover layer 300 may be damaged by an external force, thereby generating glass fragments. The glass fragments may shatter to the outside of the display device 1. According to various embodiments of the present specification, in order to prevent the shattering of the glass fragments due to the damage to the cover layer 300 or increase the durability of the cover layer 300, the display device 1 may further include at least one additional layer on the cover layer 300. For example, the display device 1 may further include a film layer or a coating layer on the cover layer 300, but various embodiments of the present specification are not limited thereto.

A side surface of the cover layer 300 may protrude further outward than a side surface of the display panel 100. For example, the side surface of the cover layer 300 may protrude further outward than an end of the bending region BR of the display panel 100, but various embodiments of the present specification are not limited thereto.

The backplate layer 600 may be disposed below the display panel 100. The backplate layer 600 may be disposed below the display panel 100 to support the display panel 100. The backplate layer 600 may include a material capable of supporting the display panel 100. For example, the backplate layer 600 may include polyethylene terephthalate (PET), polyimide (PI), or polycarbonate (PC), but various embodiments of the present specification are not limited thereto. The backplate layer 600 can maintain a constant curvature of the bending region BR when the display device 1 is bent and suppress wrinkles occurring on an upper surface of the display panel 100.

The backplate layer 600 may include a first backplate layer 610 on the main region MR and a second backplate layer 620 on the sub-region SR. The first backplate layer 610 may be disposed between the main region MR of the display panel 100 and the plate layer 800, and the second backplate layer 620 may be disposed between the sub-region SR of the display panel 100 and the plate layer 800. The backplate layer 600 may not be disposed on the bending region BR.

The plate layer 800 may be disposed between the first backplate layer 610 and the second backplate layer 620. The plate layer 800 may include a metal. For example, the plate layer 800 may include stainless steel, but various embodiments of the present specification are not limited thereto. The plate layer 800 may include a first plate layer 810 between the first backplate layer 610 and the second backplate layer 620, and a second plate layer 820 between the first plate layer 810 and the second backplate layer 620.

Bonding layers may be additionally disposed between the members 100, 200, 300, 610, 620, 810, and 820. The bonding layers may include a first bonding layer 710, a second bonding layer 720, a third bonding layer 730, a fourth bonding layer 740, a fifth bonding layer 750, a sixth bonding layer 760, and a seventh bonding layer 770.

The first bonding layer 710 may be disposed between the display panel 100 and the polarization layer 200. The first bonding layer 710 may connect or couple the display panel 100 to the polarization layer 200.

The second bonding layer 720 may be disposed between the polarization layer 200 and the cover layer 300. The second bonding layer 720 may connect or couple the polarization layer 200 to the cover layer 300.

The third bonding layer 730 may be disposed between the first backplate layer 610 and the display panel 100. The third bonding layer 730 may connect or couple the first backplate layer 610 to the display panel 100.

The fourth bonding layer 740 may be disposed between the first backplate layer 610 and the first plate layer 810. The fourth bonding layer 740 may connect or couple the first plate layer 610 to the first plate layer 810.

The fifth bonding layer 750 may be disposed between the second backplate layer 620 and the display panel 100 of the sub-region SR. The fifth bonding layer 750 may connect or couple the second backplate layer 620 to the display panel 100.

The sixth bonding layer 760 may be disposed between the second backplate layer 620 and the second plate layer 820. The sixth bonding layer 760 may connect or couple the second plate layer 620 to the second plate layer 820.

The seventh bonding layer 770 may be disposed between the first plate layer 810 and the second plate layer 820. The seventh bonding layer 770 may connect or couple the first plate layer 810 to the second plate layer 820.

The eighth bonding layer 780 may be disposed between the mold frame MFP and the cover layer MCL. The eighth bonding layer 780 may connect or couple the mold frame MFP to the cover layer MCL.

The ninth bonding layer 790 may be disposed between a fourth mold part MDP4 (or the mold part) and the housing HSP. The ninth bonding layer 790 may connect or couple the mold part MDP to the housing HSP.

Each of the first bonding layer 710 and the second bonding layer 720 may include a transparent adhesive, but various embodiments of the present specification are not limited thereto. For example, the transparent adhesive may be a transparent resin (OCR) or a transparent adhesive (OCA), but various embodiments of the present specification are not limited thereto. Each of the third bonding layer 730, the fourth bonding layer 740, the fifth bonding layer 750, the sixth bonding layer 760, the seventh bonding layer 770, the eighth bonding layer 780, and the ninth bonding layer 790 may include a pressure-sensitive adhesive (PSA), but various embodiments of the present specification are not limited thereto.

The cover layer MCL may be disposed on one surface of the bending region BR of the display panel 100. The cover layer MCL may include a plastic material and may be coated on the one surface of the bending region BR of the display panel 100 to cover the bending region BR of the display panel 100. A link line may be disposed on the bending region BR. The cover layer MCL can protect the link line from an external impact and prevent moisture penetration into the link line. In addition, the cover layer MCL may serve to position the link line on a neutral plane when the bending region BR of the display panel 100 is bent in a curved shape having a constant radius of curvature. Since the neutral plane whose a tensile force and a compressive force are zero is formed in the bending region BR and the link line is positioned on the neutral plane, when the display panel 100 is bent, the link line may receive bending stress of zero, and thus may be bent without being damaged by the bending stress.

The cover layer MCL may be in contact with side surfaces of the polarization layer 200 and the first bonding layer 710. A portion of the cover layer MCL may extend to the sub-region SR. On the sub-region SR, the cover layer MCL may be coupled to the mold frame MFP via the eighth bonding layer 780.

The data driving unit DIC may be disposed in the first pad area PA1 of the sub-region SR, and the printed circuit board FPCB may be disposed in the second pad area PA2. The printed circuit board FPCB may be electrically connected to pads on the display panel 100 via an anisotropic conductive film ACF. The cover layer MCL may not overlap the data driving unit DIC, but various embodiments of the present specification are not limited thereto.

The mold frame MFP may be disposed below the cover layer MCL.

The mold part MDP may be disposed on the cover layer MCL. The mold part MDP may cover an outer surface of the bending region BR of the display panel 100 and may be in direct contact with, for example, the cover layer MCL, a lower surface of the cover layer 300, and an upper surface, side surface, and lower surface of the mold frame MFP. The mold part MDP may also be in contact with an inner surface of the housing HSP. The mold part MDP may also be disposed inside the bending region BR. The mold part MDP may be in contact with an inner surface of the bending region BR, side surfaces of the first and second backplate layers 610 and 620, and side surfaces of the plate layers 810 and 820.

The housing HSP may be disposed on an outermost portion of the display device 1. A portion of the housing HSP extending in the thickness direction (or the third direction DR3) may be in direct contact with the cover layer 300 and the mold part MDP. A portion of the housing HSP extending in the second direction DR2 may be coupled to the mold part MDP via the ninth bonding layer 790.

FIG. 5 is a cross-sectional view along line C-Cʹ in FIG. 3.

FIG. 5 illustrates the main region MR including the display area DA and the non-display area NDA. FIG. 5 illustrates a cross-sectional view of a right region (or a short edge along one side in the first direction DR1) of the display device 1. The cross-sectional view of the right region of the display device 1 may be substantially the same as cross-sectional views of left and upper regions of the display device 1.

Referring to FIGS. 3 and 5, the mold part MDP may be in direct contact with the side surface of the display panel 100, the side surface of the first backplate layer 610, and the side surface of the first plate layer 810. The mold part MDP may be in direct contact with the side surface and lower surface of the mold frame MFP. The mold part MDP may be bonded to the housing HSP via the ninth bonding layer 790. The mold part MDP may be in contact with a lower surface of the cover layer 300 and the inner surface of the housing HSP.

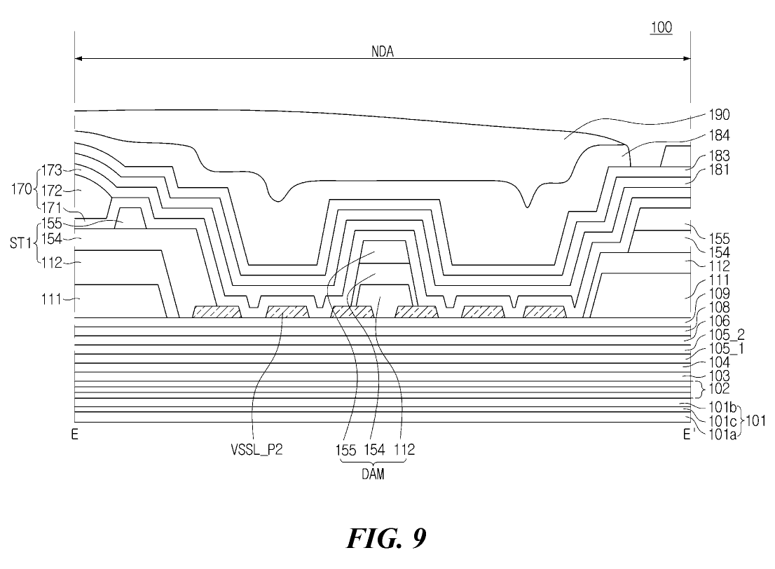

In the display device 1 according to one embodiment, the mold part MDP may include an organic material. The mold part MDP may include an organic material that repeatedly contracts and expands in response to heat. The mold part MDP is in direct contact with the non-display area NDA of the display panel 100 and is substantially deformed (expands or contracts) in response to heat, thereby causing cracks in encapsulation layers 171 and 173 (see FIG. 9) of the display panel 100 positioned in the non-display area NDA. A structure for preventing cracks according to one embodiment will be described below.

FIG. 6 is a cross-sectional view along line A-Aʹ in FIG. 1.

Referring to FIG. 6, the display panel 100 may include a substrate 101, a buffer layer 102, a first thin-film transistor 120, a second thin-film transistor 130, a storage electrode 140, a light-emitting part 150, an encapsulation part 170, a touch part 180, and an upper organic layer 190.

The substrate 101 may include one or more plastic materials. For example, the substrate 101 may be a multi-substrate including a plurality of plastic materials, such as polyimide or the like, but is not limited thereto.

The buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but is not limited thereto.

A first light-shielding layer 126 may be disposed on the buffer layer 102. The first light-shielding layer 126 can prevent light from transmitting a first semiconductor layer 123 of the first thin-film transistor 120. For example, the first semiconductor layer 123 may be disposed to overlap the first light-shielding layer 126. The first light-shielding layer 126 may be formed of a single layer or multiple layers made of any one of molybdenum (Mo), aluminum (Al), chromium (Cr), nickel (Ni), neodymium (Nd), and copper (Cu) or an alloy thereof, but is not limited thereto.

A first insulating layer 103 may be disposed on the first light-shielding layer 126. The first insulating layer 103 can prevent a short circuit between a component of the first thin-film transistor 120 and the first light-shielding layer 126. The first insulating layer 103 may be made of the same material as the buffer layer 102, but is not limited thereto. For example, the first insulating layer 103 may be made of an inorganic material, such as silicon nitride (SiNₓ), silicon oxide (SiOₓ), etc., but is not limited thereto.

The first thin-film transistor 120 may be disposed on the first insulating layer 103. The first thin-film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but is not limited thereto. The first semiconductor layer 123 may include a channel area, a source area, and a drain area.

Since the polycrystalline semiconductor layer has higher mobility than the amorphous semiconductor layer and the oxide semiconductor layer, energy consumption power can be low and reliability can be excellent. Accordingly, a driving transistor may be formed of the polycrystalline semiconductor layer.

A second insulating layer 104 may be disposed on the first semiconductor layer 123. The second insulating layer 104 may be made of the same material as the first insulating layer 103 and can prevent a short circuit between the first semiconductor layer 123 and another component of the first thin-film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or compounds thereof. The first gate electrode 122 may be disposed together with a gate line.

A third insulating layer 105 may be disposed on the first gate electrode 122. The third insulating layer 105 may be made of the same material as the first insulating layer 103 or the second insulating layer 104.

The first source electrode 121 and the first drain electrode 124 may be disposed on the third insulating layer 105.

The first source electrode 121 and the first drain electrode 124 may be electrically connected to the first semiconductor layer 123 via contact holes. The first source electrode 121 and the first drain electrode 124 may be made of a metallic material. For example, the first source electrode 121 and the first drain electrode 124 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but are not limited thereto.

The first source electrode 121 and the first drain electrode 124 may be disposed together with the data line. For example, the data line may be made of the same material as the first source electrode 121 and the first drain electrode 124 and may be formed on the same layer as the first source electrode 121 and the first drain electrode 124, but is not limited thereto.

The storage electrode 140 may be disposed to be spaced apart from the first thin-film transistor 120. The storage electrode 140 may include a first storage electrode 141, a second storage electrode 142, and a third storage electrode 143.

The first storage electrode 141 may be disposed on the same layer as the first gate electrode 122 and may be made of the same material as the first gate electrode 122, but is not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be made of the same material as the first storage electrode 141, but is not limited thereto.

The second thin-film transistor 130 may be disposed to be spaced apart from the first thin-film transistor 120 and the storage electrode 140. The second thin-film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 can prevent light from traveling to the second semiconductor layer 133 similar to the first light-shielding layer 126, thereby extending the lifetime of the second thin-film transistor 130. For example, the second semiconductor layer 133 may be disposed to overlap the second light-shielding layer 136.

A fourth insulating layer 106 may be disposed on the second light-shielding layer 136. The fourth insulating layer 106 may be made of the same material as the first insulating layer 103, the second insulating layer 104, or the third insulating layer 105, but is not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as IGZO or the like, and a silicon-based semiconductor material, such as amorphous silicon, polycrystalline silicon, etc., but is not limited thereto.

A fifth insulating layer 108 may be disposed on the second semiconductor layer 133. The fifth insulating layer 108 may be made of the same material as the first insulating layer 103, the second insulating layer 104, the third insulating layer 105, or the fourth insulating layer 106, but is not limited thereto.

The second gate electrode 132 may be disposed on the fifth insulating layer 108.

The second gate electrode 132 may be made of the same material as the first gate electrode 122. For example, the second gate electrode 132 may be formed of a single layer or multiple layers made of molybdenum (Mo), copper (Cu), titanium (Ti), aluminum (Al), chromium (Cr), gold (Au), nickel (Ni), neodymium (Nd), or compounds thereof, but is not limited thereto.

A sixth insulating layer 109 may be disposed on the second gate electrode 132. The sixth insulating layer 109 may be made of the same material as the first insulating layer 103, the second insulating layer 104, the third insulating layer 105, the fourth insulating layer 106, or the fifth insulating layer 108, but is not limited thereto.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be made of the same material as the first source electrode 121 and the first drain electrode 124 and disposed coplanarly therewith. For example, the third storage electrode 143, the second source electrode 131, and the second drain electrode 134 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but are not limited thereto.

The first thin-film transistor 120 may be a switching transistor, and the second thin-film transistor 130 may be a driving transistor, but various embodiments of the present specification are not limited thereto.

The first protective layer 111 may be disposed on the first source electrode 121 and the first drain electrode 124.

The first protective layer 111 may planarize an upper portion of the first thin-film transistor 120 and protect the first thin-film transistor 120. The first protective layer 111 may be made of an organic material. For example, the first protective layer 111 may be made of an organic material including an acrylic resin, an epoxy resin, a phenolic resin, a polyamide resin, or a polyimide resin, but is not limited thereto.

A second protective layer 112 may be disposed on the first protective layer 111. The second protective layer 112 may be made of the same material as the first protective layer 111, but is not limited thereto.

A connection electrode 145 may be disposed between the first protective layer 111 and the second protective layer 112.

The connection electrode 145 may electrically connect the first thin-film transistor 120 to the light-emitting part 150. The connection electrode 145 may be made of the same material as the first source electrode 121 and the first drain electrode 124, but is not limited thereto.

The connection electrode 145 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but is not limited thereto.

The light-emitting part 150 may be disposed on the second protective layer 112. The light-emitting part 150 may include the first electrode 151, an organic layer 152, and a second electrode 153. The first electrode 151 may serve as an anode, and the second electrode 153 may serve as a cathode, but various embodiments of the present specification are not limited thereto.

The first electrode 151 may be disposed on the second protective layer 112. The first electrode 151 may be electrically connected to the first thin-film transistor 120 via a contact hole formed in the second protective layer 112. The first electrode 151 may be a reflective electrode that reflects light, but is not limited thereto. The first electrode 151 may include a metallic material with high reflectivity, such as a stacked structure (Ti/Al/Ti) of aluminum (Al) and titanium (Ti), a stacked structure (ITO/Al/ITO) of aluminum (Al) and indium tin oxide (ITO), or an APC alloy, and may be formed of a single layer or multiple layers, but is not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer. The organic layer 152 may be an organic light-emitting layer, an inorganic light-emitting layer, a quantum dot light-emitting layer, a micro light-emitting diode, a micro mini light-emitting diode, etc., but is not limited thereto. For example, the organic layer 152 of the display panel 100 according to one embodiment of the present specification may include an organic light-emitting layer. The organic layer 152 may include a red light-emitting layer, a green light-emitting layer, and a blue light-emitting layer.

The second electrode 153 may be disposed on the organic layer 152. The second electrode 153 may be a transparent electrode that transmits light, but is not limited thereto. For example, the second electrode 153 may include a transparent conductive material, such as ITO or IZO, or a metal that transmits visible light.

A bank 154 may be disposed to expose the first electrode 151. The bank 154 may define an opening (or a light-emitting area) of the sub-pixel and may be disposed to cover an edge portion of the first electrode 151. Each of the plurality of sub-pixels may include a red light-emitting area, a green light-emitting area, and a blue light-emitting area.

A spacer 155 may be further disposed on the bank 154.

The encapsulation part 170 may be disposed on the bank 154 or the light-emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material.

A touch buffer layer 181 may be disposed on the encapsulation part 170. For example, the touch buffer layer 181 may be disposed on the third encapsulation layer 173. The touch buffer layer 181 may be made of the same material as the buffer layer 102. The first touch conductive layer may be disposed on the touch buffer layer 181. A first touch insulating layer 183 may be disposed on the first touch conductive layer. The first touch insulating layer 183 can prevent a short circuit between the touch electrodes. The first touch insulating layer 183 may include an organic or inorganic material. The second touch conductive layer may be disposed on the first touch insulating layer 183.

The first touch conductive layer may include a second touch electrode 182, and the second touch conductive layer may include a first touch electrode 185. The first touch electrode 185 may include a 1a touch electrode 185a extending in a first direction and a 1b touch electrode 185b extending in a second direction that differs from the first direction.

The second touch electrode 182 may be electrically connected to the 1a touch electrode 185a via a contact hole formed in the first touch insulating layer 183. For example, the 1a touch electrode 185a and the second touch electrode 182 may extend in the first direction.

The first touch electrode 185 and the second touch electrode 182 may include a metallic material. For example, the first touch electrode 185 and the second touch electrode 182 may be made of titanium (Ti), nickel (Ni), aluminum (Al), or an alloy thereof and may be formed of a triple layer, such as titanium (Ti)/aluminum (Al)/titanium (Ti), but is not limited thereto.

The second touch insulating layer 184 may be disposed on the second touch conductive layer. The second touch insulating layer 184 may include an organic material.

The upper organic layer 190 may be disposed on the touch part 180, but various embodiments of the present specification are not limited thereto. The upper organic layer 190 may include an organic material.

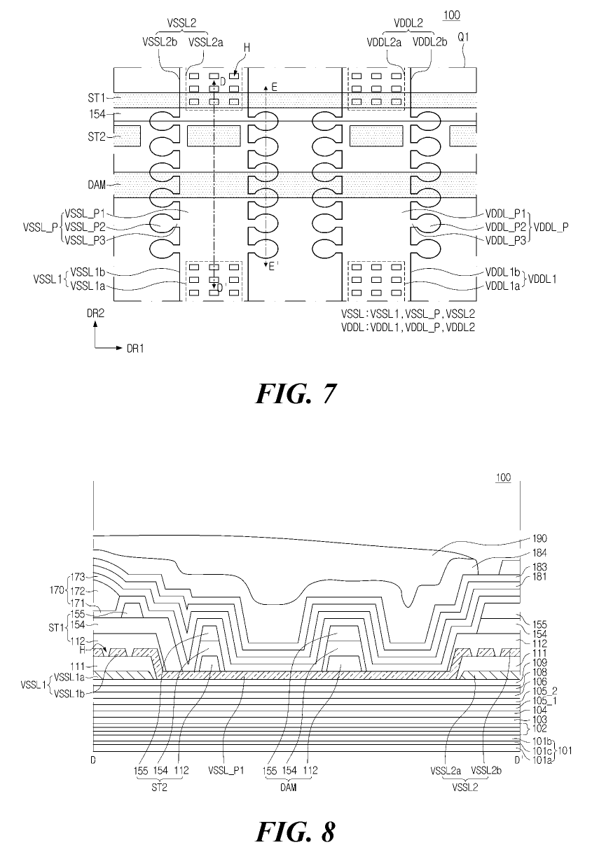

FIG. 7 is an enlarged plan view of area Q1 in FIG. 1. FIG. 8 is a cross-sectional view along line D-Dʹ in FIG. 7. FIG. 9 is a cross-sectional view along line E-Eʹ in FIG. 7.

FIG. 7 is a detailed plan view illustrating the low-potential voltage line VSSL and the high-potential voltage line VDDL according to FIG. 1. FIG. 7 illustrates the non-display area NDA positioned in the main region MR.

The low-potential voltage line VSSL and the high-potential voltage line VDDL may include first line portions VSSL1 and VDDL1, respectively. The first line portion VSSL1 of the low-potential voltage line VSSL may include a 1-1 line portion VSSL1a and a 1-2 line portion VSSL1b on the 1-1 line portion VSSL1a, and the first line portion VDDL1 of the high-potential voltage line VDDL may include a 1-1 line portion VDDL1a and a 1-2 line portion VDDL1b on the 1-1 line portion VDDL1a. Holes H passing through the 1-2 line portions VSSL1b and VDDL1b in the thickness direction may be formed in the 1-2 line portions VSSL1b and VDDL1b. The hole H may be provided as a plurality of holes. The holes H may completely pass through the 1-2 line portions VSSL1b and VDDL1b in the thickness direction. Via the hole H, gas generated within the first protective layer 111 may be discharged to the outside.

The low-potential voltage line VSSL and the high-potential voltage line VDDL may include pattern arrangement portions VSSL_P and VDDL_P, respectively. The pattern arrangement portions VSSL_P and VDDL_P may be directly connected to the first line portions VSSL1 and VDDL1, respectively. The pattern arrangement portion VSSL_P of the low-potential voltage line VSSL may include a first portion VSSL_P1 extending from the second pad area PA2 toward the display area DA (see FIG. 1), a second portion VSSL_P2 (an embossed pattern or a hammer pattern portion) disposed in a direction intersecting the direction from the second pad area PA2 toward the display area DA (see FIG. 1) from the first portion VSSL_P1, and a third portion VSSL_P3 connecting the first portion VSSL_P1 to the second portion VSSL_P2. The pattern arrangement portion VDDL_P of the high-potential voltage line VDDL may include a first portion VDDL_P1 extending from the second pad area PA2 toward the display area DA (see FIG. 1), a second portion VDDL_P2 disposed in a direction intersecting the direction from the second pad area PA2 toward the display area DA (see FIG. 1) from the first portion VDDL_P1, and a third portion VDDL_P3 connecting the first portion VDDL_P1 to the second portion VDDL_P2. For example, the direction from the second pad area PA2 toward the display area DA (see FIG. 1) may be the second direction DR2, and the direction intersecting the direction from the second pad area PA2 toward the display area DA (see FIG. 1) may be the first direction DR1, but it should be understood that the directions are relative concepts. That is, the first direction DR1 and the second direction DR2 are simply directions and may be used interchangeably. Since the pattern arrangement portion VDDL_P of the high-potential voltage line VDDL has the same structure as the pattern arrangement portion VSSL_P of the low-potential voltage line VSSL, the following description will focus on the pattern arrangement portion VSSL_P.

The second portion VSSL_P2 (or the embossed pattern) may have a rounded (or oval) shape. The second portion VSSL_P2 may also have an embossed shape. A width of the second portion VSSL_P2 in the second direction DR2 may be greater than a width of the third portion VSSL_P3 in the second direction DR2. According to the present specification, the second portion VSSL_P2 and the third portion VSSL_P3 may be disposed to protrude from the first portion VSSL_P1 in the first direction DR1 to increase the moisture permeation path along the low-potential voltage line VSSL, thereby delaying moisture permeation.

Each of the second and third portions VSSL_P2 and VSSL_P3 may be disposed at both one end (or the other end in the first direction DR1) and the other end (or one end in the first direction DR1) of one first portion VSSL_P1. That is, each of the second and third portions VSSL_P2 and VSSL_P3 may be disposed at both ends of the first portion VSSL_P1.

The first to third portions VSSL_P1 to VSSL_P3 of the pattern arrangement portion VSSL_P may all be disposed on the same layer and may include the same material, and the first to third portions VDDL_P1 to VDDL_P3 of the pattern arrangement portion VDDL_P may all be disposed on the same layer and may include the same material. The pattern arrangement portions VSSL_P and VDDL_P may be disposed on the same layer as the 1-2 line portions VSSL1b and VDDL1b, respectively.

The low-potential voltage line VSSL and the high-potential voltage line VDDL may include second line portions VSSL2 and VDDL2, respectively. The second line portions VSSL2 and VDDL2 may be directly connected to the pattern arrangement portions VSSL_P and VDDL_P, respectively. The second line portion VSSL2 of the low-potential voltage line VSSL may include a 2-1 line portion VSSL2a and a 2-2 line portion VSSL2b on the 2-1 line portion VSSL2a, and the second line portion VDDL2 of the high-potential voltage line VDDL may include a 2-1 line portion VDDL2a and a 2-2 line portion VDDL2b on the 2-1 line portion VDDL2a. The 2-1 line portion VSSL2a may be disposed on the same layer as the 1-1 line portion VSSL1a, the 2-2 line portion VSSL2b may be disposed on the same layer as the 1-2 line portion VSSL1b or the pattern arrangement portion VSSL_P, the 2-1 line portion VDDL2a may be disposed on the same layer as the 1-1 line portion VDDL1a, and the 2-2 line portion VDDL2b may be disposed on the same layer as the 1-2 line portion VDDL1b or the pattern arrangement portion VDDL_P. Holes H passing through the 2-2 line portions VSSL2b and VDDL2b in the thickness direction may be formed in the 2-2 line portions VSSL2b and VDDL2b. The hole H may be provided as a plurality of holes. The holes H may completely pass through the 2-2 line portions VSSL2b and VDDL2b in the thickness direction. Via the hole H, gas generated within the first protective layer 111 may be discharged to the outside.

As illustrated in FIG. 7, the bank 154 may cover portions of the second portions VSSL_P2 and VDDL_P2 positioned closest to the display area DA (see FIG. 1). That is, the bank 154 may be disposed on one sides of the portions of the second portions VSSL_P2 and VDDL_P2 positioned closest to the display area DA (see FIG. 1) in the second direction DR2, but may not be disposed on the other sides of the portions of the second portions VSSL_P2 and VDDL_P2 closest to the display area DA (see FIG. 1) in the second direction DR2, except for the dam DAM and the second stopper ST2.

FIG. 8 is a cross-sectional view along line D-Dʹ in FIG. 7.

Referring to FIG. 8, at least one of the insulating layers 102, 103, 104, 105-1, 105-2, 106, 108, and 109 may be disposed on the substrate 101.

The 1-1 line portion VSSL1a and the 2-1 line portion VSSL2a may be disposed on the sixth insulating layer 109. The 1-1 line portion VSSL1a and the 2-1 line portion VSSL2a may be disposed on the same layer as the first source electrode 121 in FIG. 6. The 1-1 line portion VSSL1a and the 2-1 line portion VSSL2a may be disposed in the main region MR.

The first protective layer 111 may be disposed on the 1-1 line portion VSSL1a and the 2-1 line portion VSSL2a.

The 1-2 line portion VSSL1b, the first portion VSSL_P1, and the 2-2 line portion VSSL2b may be disposed on the first protective layer 111. The 1-2 line portion VSSL1b, the first portion VSSL_P1, and the 2-2 line portion VSSL2b may be disposed on the same layer as the connection electrode 145 in FIG. 6. The 1-2 line portion VSSL1b may be disposed in the main region MR and on the underlying first protective layer 111. The 2-2 line portion VSSL2b may be disposed in the main region MR and the underlying first protective layer 111.

The 1-2 line portion VSSL1b and the 2-2 line portion VSSL2b may include holes H passing therethrough in the thickness direction. Via the hole H, gas generated within the first protective layer 111 may be discharged to the outside.

The first portion VSSL_P1 may overlap the second stopper ST2 and the dam DAM.

The second protective layer 112 may be disposed on the 1-2 line portion VSSL1b, the first portion VSSL_P1, and the 2-2 line portion VSSL2b. The second protective layer 112 may be disposed in the main region MR and may overlap the first portion VSSL_P1. The second protective layer 112 may form first layers of the dam DAM and the second stopper ST2. The dam DAM and the second stopper ST2 may each be disposed between the bending region BR (see FIG. 1) and the display area, and the dam DAM may be disposed between the second stopper ST2 and the bending region BR. The second protective layer 112 may overlap the 1-2 line portion VSSL1b and the 2-2 line portion VSSL2b and fill the holes H to be in direct contact with the first protective layer 111. The second protective layer 112 may form a first layer of the first stopper ST1, the first layer of the second stopper ST2, and the first layer of the dam DAM. The first stopper ST1 may be disposed between the second stopper ST2 and the display area. The first stopper ST1 may overlap the first line portion VSSL1. Near the first line portion VSSL1, the second protective layer 112 may completely cover the first protective layer 111, and an end of the second protective layer 112 may be positioned between an end of the first protective layer 111 and an end of the bank 154.

The bank 154 may be disposed on the second protective layer 112. The bank 154 may be disposed in the main region MR and may overlap the first portion VSSL_P1. The bank 154 may form second layers of the dam DAM, the first stopper ST1, and the second stopper ST2. Near the first line portion VSSL1, the bank 154 may completely cover the second protective layer 112.

The spacer 155 may be disposed on the bank 154. The spacer 155 may be disposed in the main region MR and may overlap the first portion VSSL_P1. The spacer 155 may form third layers of the dam DAM, the first stopper ST1, and the second stopper ST2.

The first encapsulation layer 171 may be disposed on the spacer 155. The first encapsulation layer 171 may be disposed in the main region MR, may be in direct contact with an upper surface of the bank 154, the third layer of the first stopper ST1, the second stopper ST2, and the dam DAM.

The second encapsulation layer 172 may be disposed on the first encapsulation layer 171. The second encapsulation layer 172 may terminate at the first stopper ST1, but various embodiments of the present specification are not limited thereto.

The third encapsulation layer 173 may be disposed on the second encapsulation layer 172. The third encapsulation layer 173 may be in direct contact with the first encapsulation layer 171 on an upper surface of the stopper ST1, an upper surface of the second stopper ST2, an upper surface of the dam DAM, between the first stopper ST1 and the second stopper ST2, and between the second stopper ST2 and the dam DAM.

The touch buffer layer 181 and the first touch insulating layer 183 may be disposed in the main region MR. The touch buffer layer 181 and the first touch insulating layer 183 may overlap the first stopper ST1, the second stopper ST2, and the dam DAM.

The second touch insulating layer 184 may be disposed on the first touch insulating layer 183. The upper organic layer 190 may be disposed on the second touch insulating layer 184.

FIG. 9 is a cross-sectional view along line E-Eʹ in FIG. 7.

In the description of FIG. 9, the overlapping descriptions of the parts already described with reference to FIG. 8 will be omitted.

Referring to FIG. 9, the second portion VSSL_P2 may be disposed between the sixth insulating layer 109 and the second protective layer 112 of the dam DAM. The second portion VSSL_P2 may be disposed on the same layer as the first portion VSSL_P1 in FIG. 8. The second portions VSSL_P2 positioned at the leftmost and rightmost sides may not overlap the first and second protective layers 111 and 112, and a portion of the second portion VSSL_P2 positioned at the leftmost side may be covered by the bank 154. That is, the portion of the second portion VSSL_P2 positioned at the leftmost side may be in direct contact with the bank 154. Accordingly, the stress applied to the second portion VSSL_P2 can be reduced. However, the second portion VSSL_P2 positioned at the rightmost side may not overlap the first and second protective layers 111 and 112 and the bank 154.

The dam DAM and the adjacent second portions VSSL_P2 may overlap each other. In the overlapping area of the dam DAM, one end portion of the second portion VSSL_P2 may be covered by the dam DAM, but the portion exposed by the dam DAM may be in direct contact with the first encapsulation layer 171. In an area in which the dam DAM is not disposed, side and upper surfaces of the second portion VSSL_P2 may be in direct contact with the first encapsulation layer 171.

As described above, the mold part MDP (see FIG. 3) is in direct contact with the non-display area NDA of the display panel 100 and is substantially deformed (expands or contracts) in response to heat, thereby causing cracks in the encapsulation layers 171 and 173 (see FIG. 9) of the display panel 100 positioned in the non-display area NDA.

The cracks caused in the encapsulation layers 171 and 173 may be applied to the second portions VSSL_P2 in direct contact with the first encapsulation layer 171 in the non-display area NDA. However, according to one embodiment, by covering the second portion VSSL_P2 positioned at the leftmost side at which crack propagation begins, the stress applied to the second portion VSSL_P2 can be reduced, and crack propagation can be prevented.

Hereinafter, other embodiments will be described. In the description of the following embodiments, the detailed descriptions of the components or contents already described with reference to FIGS. 1 - 9 will be omitted.

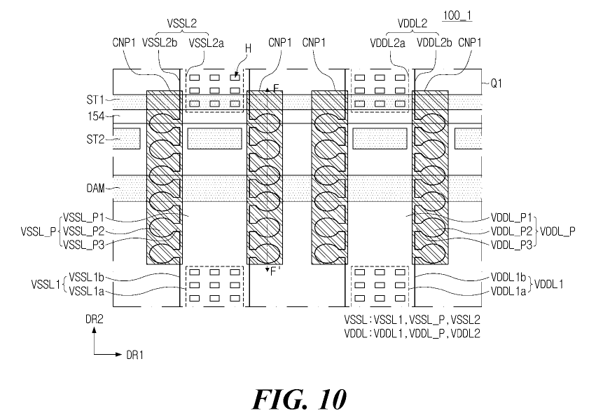

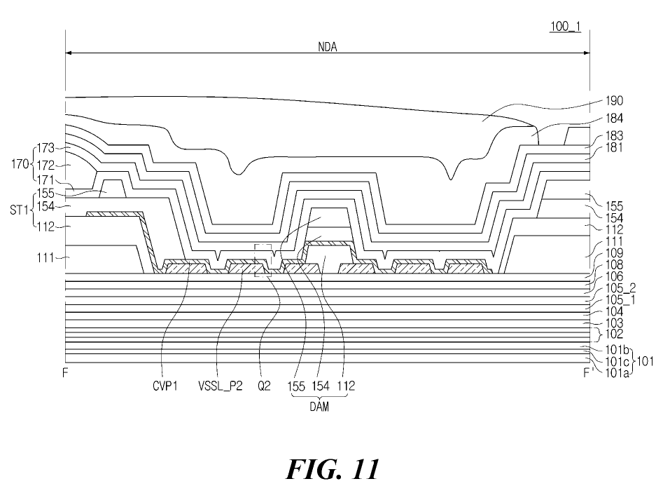

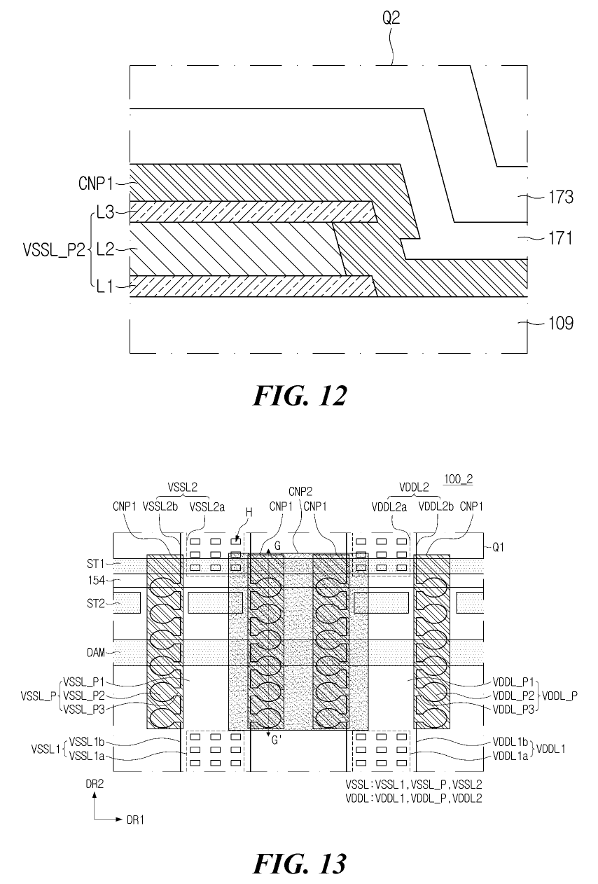

FIG. 10 is a plan view of a display panel according to still another embodiment. FIG. 11 is a cross-sectional view along line F-Fʹ in FIG. 10. FIG. 12 is an enlarged cross-sectional view of area Q2 in FIG. 11.

Referring to FIGS. 10-12, a display panel 100_1 according to the present embodiment differs from the display panel 100 according to FIG. 7 in that it further includes a first cover pattern CVP1.

More specifically, the first cover pattern CVP1 may be provided as a plurality of first cover patterns. The plurality of first cover patterns CVP1 may overlap the second portions VSSL_P2.

For example, the second portions VSSL_P2 of the pattern arrangement portion VSSL_P of the low-potential voltage line VSSL may be disposed on both ends of the first portion VSSL_P1. The second portions VSSL_P2 positioned on the other end of the first portion VSSL_P1 in the first direction DR1 may be disposed to be spaced apart from each other in the second direction DR2 (or a column direction), and the second portions VSSL_P2 positioned on one end of the first portion VSSL_P1 in the first direction DR1 may be disposed to be spaced apart from each other in the second direction DR2 (or the column direction). Any one of the first cover patterns CVP1 may cover the second portions VSSL_P2 positioned on the other end of the first portion VSSL_P1 in the first direction DR1. The other of the first cover patterns CVP1 may cover the second portions VSSL_P2 positioned on the one end of the first portion VSSL_P1 in the first direction DR1.

For example, the second portions VDDL_P2 of the pattern arrangement portion VDDL_P of the high-potential voltage line VDDL may be disposed on both ends of the first portion VDDL_P1. The second portions VDDL_P2 positioned on the other end of the first portion VDDL_P1 in the first direction DR1 may be disposed to be spaced apart from each other in the second direction DR2 (or the column direction), and the second portions VDDL_P2 positioned on one end of the first portion VDDL_P1 in the first direction DR1 may be disposed to be spaced apart from each other in the second direction DR2 (or the column direction). Any one of the first cover patterns CVP1 may cover the second portions VDDL_P2 positioned on the other end of the first portion VDDL_P1 in the first direction DR1. The other of the first cover patterns CVP1 may cover the second portions VDDL_P2 positioned on the one end of the first portion VDDL_P1 in the first direction DR1.

Each of the first cover patterns CVP1 may overlap the first stopper ST1 and the dam DAM, but may not overlap the second stopper ST2. Each of the first cover patterns CVP1 may overlap portions of the first portions VSSL_P1 and VDDL_P1 and the third portion VSSL_P3 and VDDL_P3.

Adjacent first cover patterns CVP1 may be disposed to be spaced apart from each other in the first direction DR1.

As illustrated in FIG. 11, the first cover pattern CVP1 may be disposed between the second protective layer 112 and the bank 154 and may extend to be in direct contact with a plurality of second portions VSSL_P2. The first cover pattern CVP1 in contact with each second portion VSSL_P2 may be in direct contact with the first encapsulation layer 171. On the dam DAM, the first cover pattern CVP1 may be disposed between the underlying first layer and the overlying second layer.

The first cover pattern CVP1 may be positioned on the same layer as the first electrode 151 in FIG. 6.

As illustrated in FIG. 12, the second portion VSSL_P2 includes a first layer L1, a second layer L2 on the first layer L1, and a third layer L3 on the second layer L2, and the first cover pattern CVP1 may be in direct contact with each of the first layer L1, the second layer L2, and the third layer L3.

The first layer L1 and the third layer L3 may include the same material, and a material of the first layer L1 may differ from a material of the second layer L2. For example, each of the first layer L1 and the third layer L3 may include titanium (Ti), and the second layer L2 may include aluminum (Al), but various embodiments of the present specification are not limited thereto.

Ends of the first layer L1 and the third layer L3 may protrude further outward than an end of the second layer L2. The first cover pattern CVP1 may be in contact with an upper surface, side surfaces, and a lower surface of the third layer L3 that protrudes further outward than the end of the second layer L2, may be in contact with side surfaces of the second layer L2, and may be in direct contact with an upper surface and side surfaces of the first layer L1 that protrude further outward than the end of the second layer L2.

When the first cover pattern CVP1 is not disposed, cracks may occur in the first encapsulation layer 171 due to tips formed by the first layer L1 to the third layer L3 (portions in which the ends of the first layer L1 and the third layer L3 protrude further outward than the end of the second layer L2).

However, according to various embodiments of the present specification, the first cover pattern CVP1 may cover the tips, thereby not only preventing cracks in the first encapsulation layer 171, but also preventing cracks in the embossed pattern or reducing stress applied to the embossed pattern.

Since the remaining parts have been described above with reference to FIGS. 7 and 9, the detailed descriptions thereof will be omitted below.

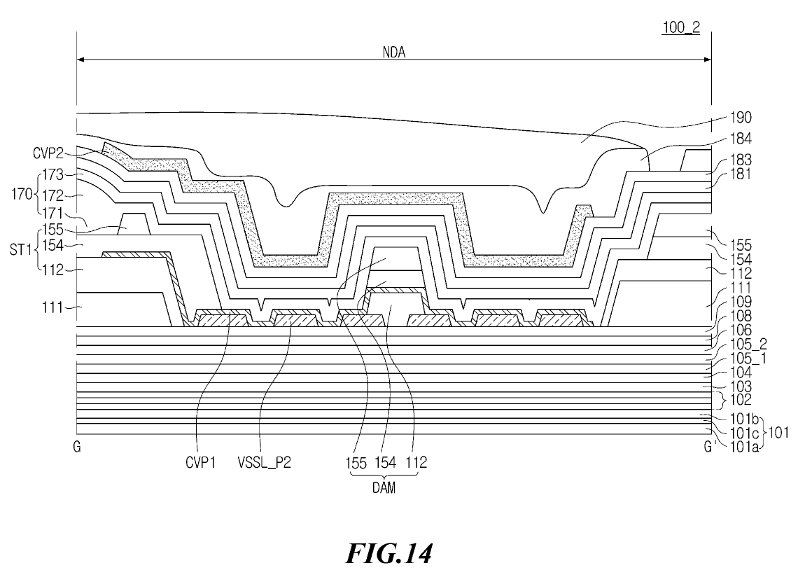

FIG. 13 is a plan view of a display panel according to another embodiment. FIG. 14 is a cross-sectional view along line G-Gʹ in FIG. 13.

Referring to FIGS. 13 and 14, a display panel 100_2 according to the present embodiment differs from the display panel 100_1 according to FIGS. 11 and 12 in that it further includes a second cover pattern CVP2.

More specifically, the second cover pattern CVP2 may cover the first cover pattern CVP1 that covers the second portions VSSL_P2 positioned on the one end of the first portion VSSL_P1 in the first direction DR1, and the first cover patterns CVP1 that cover the second portions VDDL_P2 positioned on the other end of the first portion VDDL_P1 in the first direction DR1. The second cover pattern CVP2 may also be disposed between the first cover pattern CVP1 covering the second portions VSSL_P2 positioned on the one end of the first portion VSSL_P1 in the first direction DR1 and the first cover pattern CVP1 covering the second portions VDDL_P2 positioned on the other end of the first portion VDDL_P1 in the first direction DR1.

The second cover pattern CVP2 may overlap the first stopper ST1 and the dam DAM and overlap a portion of the second stopper ST2.

The second cover pattern CVP2 may be disposed between the first touch insulating layer 183 and the second touch insulating layer 184 and may be positioned on the same layer as the first touch electrode 185 in FIG. 6 , but various embodiments of the present specification are not limited thereto.

According to various embodiments of the present specification, by including the second cover pattern CVP2 covering the second portion VSSL_P2, cracks in the second portion VSSL_P2 can be prevented, or stress applied to the embossed pattern can be reduced.

Since the remaining parts have been described above with reference to FIGS. 10 and 11, the detailed descriptions thereof will be omitted below.

Additional embodiments of the present specification are discussed below.

In some embodiments, a display device may include a substrate having a display area and a non-display area adjacent to the display area. A conductive member (e.g., power line) may be disposed in the non-display area of the substrate. The conductive member may include a first portion extending in a first direction and a plurality of second portions extending from the first portion in a second direction that is transverse to the first direction. A bank may be disposed adjacent to the conductive member.

In certain embodiments, the bank may overlap a second portion positioned closest to the display area. At least one other second portion among the plurality of second portions may remain not overlapped by the bank. The selective overlap of the bank with the second portion closest to the display area may assist in managing stress distribution or crack propagation in the peripheral region of the display device.

In some embodiments, each of the plurality of second portions may have a curved shape. The plurality of second portions may be spaced apart from each other along the first direction. The curved configuration of the second portions and their spacing along the first direction may contribute to an extended moisture permeation path along the conductive member within the non-display area.

In certain embodiments, each second portion may include an upper surface and a side surface. The bank may be in direct contact with the upper surface and the side surface of the second portion positioned closest to the display area among the plurality of second portions. Direct contact between the bank and these surfaces of the second portion may provide mechanical reinforcement and may reduce stress concentrations near the display area.

In some embodiments, the bank may be disposed on one side of the second portion such that an opposite side of the second portion remains exposed by the bank. This configuration may allow a portion of the second portion to remain uncovered while still enabling the bank to provide structural support or stress mitigation to a selected portion of the conductive member.

In certain embodiments, each curved second portion of the plurality of second portions may be formed of a stacked metallic structure. The stacked metallic structure may include multiple conductive layers arranged vertically relative to the substrate. Such a stacked configuration may improve electrical performance and structural integrity of the conductive member.

In some embodiments, the stacked metallic structure may include a first layer L1, an intermediate second layer L2, and a third layer L3. The first layer and the third layer may protrude further outward than the intermediate second layer. As a result of the protruding configuration, metal tips may be formed at the edges of the first and third layers relative to the intermediate second layer.

In certain embodiments, the first layer and the third layer may include the same material. For example, the first and third layers may both include titanium or another suitable conductive metal. The intermediate second layer may include a material different from the material of the first layer, such as aluminum or another conductive material. The use of different materials in the stacked metallic structure may improve adhesion, conductivity, or mechanical reliability.

In some embodiments, the display device may further include a first cover pattern CVP1 disposed in the non-display area. The first cover pattern may be configured to contact portions of the stacked metallic structure. For example, the first cover pattern may be in direct contact with an upper surface, a side surface, and a lower surface of a portion of the third layer that protrudes further outward than the intermediate second layer. The first cover pattern may also contact a side surface of the intermediate second layer and an upper surface and a side surface of a portion of the first layer that protrudes further outward than the intermediate second layer. In this manner, the first cover pattern may shield metal tips formed by the protruding first and third layers, thereby reducing the likelihood of crack initiation or propagation in adjacent layers.

In certain embodiments, the display device may further include a second cover pattern CVP2 disposed on the first cover pattern. The second cover pattern may be positioned between a first touch insulating layer and a second touch insulating layer of a touch sensing structure of the display device. The placement of the second cover pattern between these layers may provide additional protection and structural stability.

In some embodiments, the display device may include a plurality of first cover patterns and a second cover pattern disposed on the plurality of first cover patterns. The plurality of first cover patterns may be spaced apart from each other in the first direction. The second cover pattern may overlap at least two of the plurality of first cover patterns, thereby providing a continuous protective structure over multiple portions of the conductive member.

In certain embodiments, the display device may further include a dam DAM extending in the second direction. The dam may overlap the first portion of the conductive member and at least a portion of adjacent second portions. The dam may function as a barrier structure that limits the flow of encapsulation materials or defines a boundary within the non-display area.

In some embodiments, a first stopper ST1 may be disposed between the dam and the display area. Both the dam and the first stopper may extend continuously in the second direction. The first stopper may assist in controlling the spread of encapsulation materials or organic layers within the display device.

In certain embodiments, a second stopper ST2 may be disposed between the first stopper and the dam. The second stopper may overlap the first portion of the conductive member and may be positioned between adjacent second portions in the second direction. The arrangement of the second stopper relative to the conductive member and the second portions may further contribute to mechanical stability and crack suppression in the peripheral region of the display device.

Further embodiments of the present specification are discussed below.

According to various embodiments of the present specification, there is provided a display device including a substrate including a display area and a non-display area around the display area, a voltage line disposed in the non-display area on the substrate, and a bank around the power line, in which the voltage line includes a first portion extending in a first direction and a second portion positioned in a second direction intersecting the first direction from the first portion and having a curved shape, the second portion is provided as a plurality of second portions, which are disposed to be spaced apart from each other in the first direction, and a second portion disposed close to the display area among the plurality of second portions is covered by the bank.

In the display device according to various embodiments of the present specification, the voltage line may further include a third portion connecting the first portion to the second portion, and a width of the second portion in the first direction may be greater than a width of the third portion in the first direction.

In the display device according to various embodiments of the present specification, the second portion may be disposed on each of one side of the first portion in the second direction and the other side of the first portion in the second direction.

In the display device according to various embodiments of the present specification, the voltage line may include a high-potential voltage line or a low-potential voltage line.

In the display device according to various embodiments of the present specification, the non-display area may include a pad area in which the power pad is disposed, and each of the first portion and the second portion may be disposed between the pad area and the display area.

The display device according to various embodiments of the present specification may further include a dam including at least one organic material and extending in the second direction, in which the dam may overlap adjacent second portions and the first portion.

In the display device according to various embodiments of the present specification, the dam may continuously extend in the second direction.

The display device according to various embodiments of the present specification may further include a first stopper between the dam and the display area, in which the first stopper may extend in the second direction and include the at least one organic material.

The display device according to various embodiments of the present specification may further include a second stopper between the first stopper and the dam, in which the second stopper may include the at least one organic material, and the second stopper may overlap the first portion and may be disposed between adjacent second portions in the second direction.

In the display device according to various embodiments of the present specification, the at least one organic material may include at least one of a protective layer, the bank, and a spacer.

In the display device according to various embodiments of the present specification, the protective layer may include a first protective layer on the substrate, and a second protective layer between the first protective layer and the bank, and an end of the second protective layer may be positioned between an end of the bank and an end of the first protective layer.

According to various embodiments of the present specification, there is provided a display device including a substrate including a display area and a non-display area around the display area, a voltage line disposed in the non-display area on the substrate, a first cover pattern, a dam overlapping the power line, a first stopper between the dam and the display area, and a second stopper between the first stopper and the dam, in which the voltage line includes a first portion extending in a first direction, and a second portion positioned in a second direction intersecting the first direction from the first portion and having a curved shape, the second portion is provided as a plurality of second portions, which are disposed to be spaced apart from each other in the first direction, the dam and the first stopper continuously extend in the second direction, the second stopper overlaps the first portion and is disposed between adjacent second portions in the second direction, and the first cover pattern overlaps the plurality of second portions disposed to be spaced apart from each other in the first direction.

The display device according to various embodiments of the present specification may further include a light-emitting part disposed on the substrate on the display area, in which the light-emitting part may include a first electrode, an organic layer on the first electrode, and a second electrode on the organic layer, and the first cover pattern may be disposed on the same layer as the first electrode.

In the display device according to various embodiments of the present specification, the first cover pattern may be in direct contact with the second portion.

In the display device according to various embodiments of the present specification, the second portion may include a first layer, a second layer on the first layer, and a third layer on the second layer, the first cover pattern may be in contact with each of the first layer, the second layer, and the third layer, the first layer and the third layer may include the same material, and a material of the first layer may differ from a material of the second layer.

In the display device according to various embodiments of the present specification, the first cover pattern may overlap the first stopper and the dam and may not overlap the second stopper.

In the display device according to various embodiments of the present specification, the voltage line may include a first voltage line and a second voltage line spaced apart from the first voltage line in a first direction, the first voltage line may be a low-potential voltage line, and the second voltage line may be a high-potential voltage line.

In the display device according to various embodiments of the present specification, a second portion of each of the first voltage line and the second voltage line may be disposed on each of one side of the first portion in the first direction and the other side of the first portion in the first direction.

The display device according to various embodiments of the present specification may further include a plurality of second portions positioned on one side of the first voltage line in the first direction and a second cover pattern overlapping the plurality of second portions positioned on the other side of the second voltage line in the first direction.

In the display device according to various embodiments of the present specification, the second cover pattern may overlap the first stopper, the second stopper, and the dam.

According to various embodiments of the present specification, the moisture permeation path can be increased by having the embossed (or rounded) second portion protruding in the direction intersecting the extension direction of the high-potential voltage line or the low-potential voltage line positioned in the non-display area.

According to various embodiments of the present specification, the stress applied to the embossed pattern can be reduced by partially covering the embossed pattern (or the hammer pattern portion or the second portion) near the display area with the bank.

According to various embodiments of the present specification, cracks in the embossed pattern can be prevented, or the stress applied to the embossed pattern can be reduced by including the first cover pattern and/or the second cover pattern, which cover the embossed pattern.

According to various embodiments of the present specification, cracks in the first encapsulation layer can be prevented by including the first cover pattern that covers the embossed pattern.

According to various embodiments of the present specification, the low-power display device capable of extending lifetime can be provided.

However, effects obtainable from the present specification are not limited to the above effects, and other effects that are not described will be able to be clearly understood by those skilled in the art to which the present specification pertains based on the following description.

Although various embodiments of the present disclosure have been described with reference to the accompanying drawings, it will be understood by those skilled in the art that the above-described technical configuration of the present disclosure may be implemented in other specific forms without changing the technical spirit or essential features of the present disclosure. Accordingly, it should be understood that the above-described embodiments are illustrative and not restrictive in all aspects. In addition, the scope of the present disclosure is described by the claims to be described below rather than the detailed description. In addition, the meaning and scope of the claims and all changed or modified forms derived from the equivalent concept should be construed as being included in the scope of the present disclosure.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device, comprising:
a substrate including a display area, and a non-display area around the display area;
a voltage line disposed in the non-display area on the substrate; and
a bank around the power line,
wherein the voltage line includes:
a first portion extending in a first direction; and
a second portion positioned in a second direction intersecting the first direction from the first portion and having a curved shape,
the second portion is provided as a plurality of second portions, which are disposed to be spaced apart from each other in the first direction, and
a second portion disposed closest to the display area among the plurality of second portions is covered by the bank.

2. The display device of claim 1, wherein the voltage line further includes a third portion connecting the first portion to the second portion, and a width of the second portion in the first direction is greater than a width of the third portion in the first direction.

3. The display device of claim 1, wherein the second portion is disposed on one side of the first portion in the second direction and the other side of the first portion in the second direction.

4. The display device of claim 1, wherein the voltage line includes a high-potential voltage line or a low-potential voltage line.

5. The display device of claim 1, wherein the non-display area includes a pad area in which a power pad is disposed, and each of the first portion and the second portion is disposed between the pad area and the display area.

6. The display device of claim 1, further comprising a dam including at least one organic material and extending in the second direction, wherein the dam overlaps adjacent ones of the second portions and the first portion.

7. The display device of claim 6, wherein the dam continuously extends in the second direction.

8. The display device of claim 6, further comprising a first stopper between the dam and the display area, wherein the first stopper extends in the second direction and includes the at least one organic material.

9. The display device of claim 8, further comprising a second stopper between the first stopper and the dam,
wherein the second stopper includes the at least one organic material, and
wherein the second stopper overlaps the first portion and is disposed between adjacent second portions in the second direction.

10. The display device of claim 6, wherein the at least one organic material includes at least one of a protective layer, the bank, and a spacer.

11. The display device of claim 10, wherein the protective layer includes a first protective layer on the substrate, and a second protective layer between the first protective layer and the bank, and an end of the second protective layer is positioned between an end of the bank and an end of the first protective layer.

12. A display device comprising:
a substrate including a display area and a non-display area adjacent to the display area;
a voltage line disposed in the non-display area on the substrate;
a first cover pattern;
a dam overlapping the power line;
a first stopper between the dam and the display area in a plan view; and
a second stopper between the first stopper and the dam in a plan view,
wherein the voltage line includes:
a first portion extending in a first direction; and
a second portion positioned in a second direction intersecting the first direction from the first portion and having a curved shape,
the second portion is provided as a plurality of second portions, which are disposed to be spaced apart from each other in the first direction,
the dam and the first stopper continuously extend in the second direction,
the second stopper overlaps the first portion and is disposed between adjacent second portions in the second direction, and
the first cover pattern overlaps the plurality of second portions disposed to be spaced apart from each other in the first direction.

13. The display device of claim 12, further comprising a light-emitting part disposed on the substrate on the display area, wherein the light-emitting part includes a first electrode, an organic layer on the first electrode, and a second electrode on the organic layer, and the first cover pattern is disposed on the same layer as the first electrode.

14. The display device of claim 12, wherein the first cover pattern is in direct contact with one of the plurality of second portions.

15. The display device of claim 14, wherein the second portion includes a first layer, a second layer on the first layer, and a third layer on the second layer, the first cover pattern is in contact with each of the first layer, the second layer, and the third layer, the first layer and the third layer include the same material, and a material of the first layer differs from a material of the second layer.

16. The display device of claim 12, wherein the first cover pattern overlaps the first stopper and the dam and does not overlap the second stopper.

17. The display device of claim 12, wherein the voltage line includes a first voltage line and a second voltage line spaced apart from the first voltage line in a first direction, the first voltage line is a low-potential voltage line, and the second voltage line is a high-potential voltage line.

18. The display device of claim 17, wherein a second portion of each of the first voltage line and the second voltage line is disposed on each of one side of the first portion in the first direction and the other side of the first portion in the first direction,
wherein the display device further comprises a plurality of second portions positioned on one side of the first voltage line in the first direction and a second cover pattern overlapping the plurality of second portions positioned on the other side of the second voltage line in the first direction, and
wherein the second cover pattern overlaps the first stopper, a portion of the second stopper, and the dam.

19. A display device, comprising:
a substrate including a display area and a non-display area adjacent to the display area;
a conductive member disposed in the non-display area, the conductive member including a first portion extending in a first direction and a plurality of second portions extending from the first portion in a second direction that is transverse to the first direction; and
a bank adjacent to the conductive member,
wherein the bank overlaps a second portion positioned closest to the display area, and
wherein at least one other second portion among the plurality of second portions is not overlapped by the bank.

20. The display device of claim 19, wherein each of the plurality of second portions has a curved shape and the plurality of second portions are spaced apart from each other along the first direction.
